(19) United States
(12) Patent Application Publication
(10) Pub. No.: US 2022/0344292 A1
(43) Pub. Date: Oct. 27, 2022

(54) DESCENDING-TYPE PADS OF SEMICONDUCTOR CHIP

(71) Applicant: Novatek Microelectronics Corp., Hsinchu (TW)

(72) Inventors: Huan-Teng Cheng, Hsinchu City (TW); Huang-Chin Tang, Hsinchu County (TW); Chien-Chen Ko, Hsinchu City (TW)

(73) Assignee: Novatek Microelectronics Corp., Hsinchu (TW)

(21) Appl. No.: 17/727,848

(22) Filed: Apr. 25, 2022

Related U.S. Application Data
(60) Provisional application No. 63/179,525, filed on Apr. 25, 2021.

(51) Int. Cl. H01L 23/00

(52) U.S. Cl. CPC H01L 24/06; H01L 24/04; H01L 2224/06177; H01L 2224/0401

(57) ABSTRACT

The disclosure provides a semiconductor chip suit for driving a display panel. The semiconductor chip includes a first pad group and a second pad group. The first pad group and the second pad group are disposed at a first long side of the semiconductor chip. The first distance from the first pad group to the edge of the first long side is different from the second distance from the second pad group to the edge of the first long side. The first pad group and the second pad group belong to a first pad row disposed at the first long side. The first pad group comprises a plurality of pads which are closer to the middle of the first pad row than the second pad group.

### CROSS-REFERENCE TO RELATED APPLICATION

This application claims the priority benefit of U.S. application Ser. No. 63/179,525, filed on Apr. 25, 2021. The entirety of the above-mentioned patent application is hereby incorporated by reference herein and made a part of this specification.

### BACKGROUND

### 1. Technical Field

The disclosure relates to a circuit layout, and in particular to a pad layout of a semiconductor chip.

### 2. Description of Related Art

Chip on glass (COG) packaging technology allows the arrangement of a semiconductor chip on a glass substrate. Generally speaking, semiconductor chips are arranged in the border region of the panel. Reducing the width of the border region of the COG panels can improve the screen-to-body ratio (ratio of the effective display area to the overall area). For a panel with COG packaging technology, there is no other effective method to reduce the border region other than reducing the size of semiconductor chip.

FIG. 1 is a schematic layout diagram of pads of a conventional semiconductor chip IC1. A panel 100 shown in FIG. 1 may be a display panel or a touch panel. The panel 100 includes an effective function region EF1 and a border region BRD1. FIG. 1 does not show the specific layout of the effective function region EF1 (such as the display region or the touch region). The COG packaging technology may allow the semiconductor chip IC1 to be arranged in the border region BRD1 of the panel 100. Multiple pads PAD1 of the semiconductor chip IC1 may be electrically connected to different driving lines (such as touch sensing lines, data lines, or scanning lines) of the effective function region EF1 of the panel 100 through multiple wires in a fan-out region FR1. Generally speaking, because of layout design rules such as line width and line pitch, the reduction in a height HF of the fan-out region FR1 is limited. Therefore, based on the limitation of the height HF of the fan-out region FR1, there is a limit to the reduction in the width of the border region BRD1.

It should be noted that the contents of the “prior art” section are configured to assist in understanding the disclosure. Some of the contents (or all of the contents) disclosed in the “prior art” section may not be the conventional technology known to those with ordinary knowledge in the art. The contents disclosed in the “prior art” section do not mean that the contents have been known by those with ordinary knowledge in the art prior to the application of the disclosure.

### SUMMARY

The disclosure provides a semiconductor chip, which facilitates further reduction in the width in the border region of a display panel.

In an embodiment of the disclosure, the semiconductor chip is configured to drive a display panel. The semiconductor chip includes a first pad group and a second pad group. The first pad group is disposed at a first long side of the semiconductor chip. The second pad group is disposed at the first long side of the semiconductor chip. A first distance from the first pad group to an edge of the first long side is different from a second distance from the second pad group to the edge of the first long side. The first pad group and the second pad group belong to a first pad row disposed at the first long side. The first pad group comprises a plurality of pads which are closer to the middle of the first pad row than the second pad group.

Based on the above, the semiconductor chip according to the embodiments of the disclosure has a descending-type pad layout, which facilitates further advancement of the position of the semiconductor chip toward the fan-out region of the display panel. Therefore, the pad layout of the semiconductor chip facilitates reduction in the width of the border region of the display panel.

In order to make the above features and advantages of the disclosure more obvious and understandable, the following specific examples are described in detail in conjunction with the attached drawings.

### BRIEF DESCRIPTION OF THE DRAWINGS

FIG. 1 is a schematic layout diagram of pads of a conventional semiconductor chip.

FIG. 2 is a schematic diagram of a pad layout of a semiconductor chip according to an embodiment of the disclosure.

FIG. 3 is a schematic diagram of a pad layout of a semiconductor chip according to another embodiment of the disclosure.

FIG. 4 is a schematic diagram illustrating a layout of left pads shown in FIG. 3 according to an embodiment of the disclosure.

FIG. 5 is a schematic diagram illustrating a layout of a fan-out region between left pads shown in FIG. 3 and a display panel according to an embodiment of the disclosure.

FIG. 6 is a schematic diagram illustrating a layout of a fan-out region between left pads shown in FIG. 3 and a large-size display panel according to an embodiment of the disclosure.

FIG. 7 is a schematic diagram of a pad layout of a semiconductor chip according to another embodiment of the disclosure.

FIG. 8A is a schematic diagram of a pad layout of a semiconductor chip according to yet another embodiment of the disclosure.

FIG. 8B is a schematic diagram of a pad layout of a semiconductor chip according to another embodiment of the disclosure.

FIG. 9 is a schematic diagram of a pad layout of a semiconductor chip according to still another embodiment of the disclosure.

FIG. 10 is a schematic diagram of a pad layout of a semiconductor chip according to yet another embodiment of the disclosure.

FIG. 11 is a schematic diagram illustrating two cross-sections of a semiconductor chip along a cross-section line AB shown in FIG. 10 under different design conditions according to yet another embodiment of the disclosure.

FIG. 12 is a schematic diagram illustrating a layout of descending-type pads of a semiconductor chip according to another embodiment of the disclosure.

FIG. 13 is a schematic diagram illustrating two cross-sections of the semiconductor chip along a cross-section line AB shown in FIG. 12 under different design conditions according to yet another embodiment of the disclosure.

FIG. 14 is a schematic layout diagram of descending-type pads of a semiconductor chip according to still yet another embodiment of the disclosure.

FIG. 15 is a schematic diagram illustrating a layout of descending-type pads of a semiconductor chip according to still another embodiment of the disclosure.

FIG. 16 is a schematic diagram illustrating a layout of descending-type pads of a semiconductor chip according to another embodiment of the disclosure.

FIG. 17 is a schematic diagram illustrating a layout of descending-type pads of a semiconductor chip according to still another embodiment of the disclosure.

FIG. 18 is a schematic layout diagram of descending-type pads of a semiconductor chip according to still yet another embodiment of the disclosure.

FIG. 19 is a schematic diagram illustrating an asymmetric layout of descending-type pads of a semiconductor chip according to another embodiment of the disclosure.

FIG. 20 is a schematic diagram illustrating an asymmetric layout of descending-type pads of a semiconductor chip according to yet another embodiment of the disclosure.

FIG. 21 is a schematic diagram illustrating an asymmetric layout of descending-type pads of a semiconductor chip according to another embodiment of the disclosure.

FIG. 22 is a schematic diagram illustrating a layout of descending-type pads of a semiconductor chip according to still yet another embodiment of the disclosure.

FIG. 23 is a schematic layout diagram of descending-type pads of a semiconductor chip according to still yet another embodiment of the disclosure.

FIG. 24 is a schematic layout diagram of descending-type pads of a semiconductor chip according to still yet another embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numbers are used in the drawings and the description to refer to the same or like parts.

The word “coupled (or connected)” used in the whole text of this specification (including claims) may refer to any direct or indirect connection means. For example, if it is described that the first device is coupled (or connected) to the second device, it should be interpreted that the first device may be directly connected to the second device, or the first device may be indirectly connected to the second device through other devices or some connection means. The terms “first” and “second” mentioned in the whole specification (including claims) are used to name elements or distinguish different embodiments or ranges, but not to limit the upper or lower limit of the number of elements, nor to limit the order of elements. In addition, wherever possible, elements/components/steps using the same reference numerals in the drawings and embodiments represent the same or similar parts. Elements/components/steps using the same reference numerals or using the same terms in different embodiments can be cross-referenced with each other with respect to the relevant descriptions.

In a panel 100 shown in FIG. 1, because of layout design rules such as line width and line pitch, reduction in a height HF of a fan-out region FR1 is limited. Although the height HF of the fan-out region FR1 cannot be further reduced, if the position of a semiconductor chip IC1 can be further advanced toward the fan-out region FR1 of the panel 100, the distance between the semiconductor chip IC1 and an effective function region EF1 can be reduced, thereby facilitating further reduction in a width of a border region BRD1. The following are some embodiments of the disclosure that illustrate several embodiments of “further advancement of the position of the semiconductor chip toward the fan-out region”.

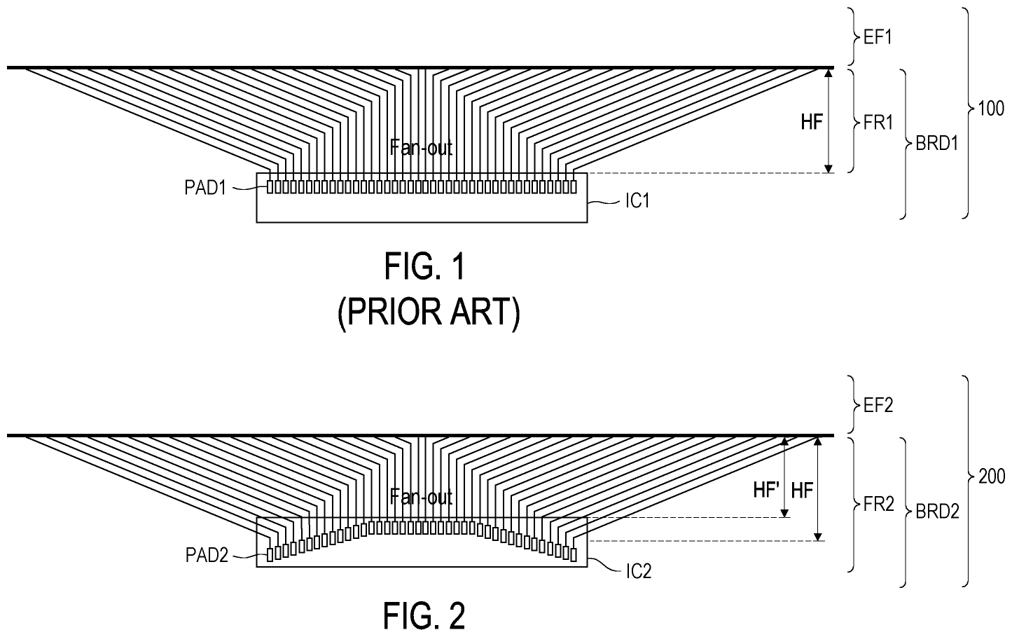

FIG. 2 is a schematic diagram of a pad layout of a semiconductor chip IC2 according to an embodiment of the disclosure. A panel may be a display panel, a touch panel, a display panel with embedded touch panel (a.k.a. touch display panel), or a display panel with embedded touch panel and embedded fingerprint sensing panel. In FIG. 2, a display panel 200 may be anyone of the aforementioned types of display panels. The display panel 200 includes an effective function region EF2 and a border region BRD2. FIG. 2 does not show the specific layout of the effective function region EF2 (such as the display active area). A chip on glass (COG) packaging technology may allow the semiconductor chip IC2 to be arranged in the border region BRD2 of the display panel 200. Multiple pads PAD2 of the semiconductor chip IC2 may be electrically connected to different driving lines (such as touch sensing lines, data lines or scanning lines) of the effective function region EF2 of the display panel 200 through multiple wires in a fan-out region FR2. The semiconductor chip IC2 is suitable for driving different driving lines of the display panel 200. The pads PAD2 shown in FIG. 2 may be pads disposed at a first long side (e.g. an output lead bump side, OLB side) of the semiconductor chip IC2. The first long side is a side where most of output lead bump pads of the semiconductor chip IC2 are disposed. FIG. 2 does not show the pads on a second long side (e.g. an input lead bump side, ILB side) opposite to the first long side of the semiconductor chip IC2 for the sake of graph simplicity. In the embodiment shown in FIG. 2, the height of the fan-out region FR1 is denoted as HF.

In the embodiment shown in FIG. 2, multiple the pads PAD2 of the semiconductor chip IC2 are divided into a left part, a middle part and a right part. The middle part of the pads PAD2 is disposed along the horizontal direction (an edge direction on the OLB side) in FIG. 2, while the left and right parts of the pads PAD2 are disposed along different oblique directions. The oblique direction is a direction of a line connecting the center of each pad or the center of each pad group in the same side (left or right) of the middle part of the pads. That is, the arrangement of the multiple pads PAD2 of the semiconductor chip IC2 looks like descending toward the fan-out region FR2 (as shown in FIG. 2), and such arrangement of the pads PAD2 may be referred to as “a descending-type pad layout”. Since the pads PAD2 of the semiconductor chip IC2 are arranged as descending toward the fan-out region FR2, the position of the semiconductor chip IC2 may be further advanced toward the fan-out region FR2 of the display panel 200, such that a distance HF' between the semiconductor chip IC2 and the effective function region EF2 of the display panel 200 may be smaller than the height HF of the fan-out region FR2. The reduction in the distance HF' from the semiconductor chip IC2 to the effective function region EF2 indicates that a width of the border region BRD2 of the display panel 200 may be further reduced.

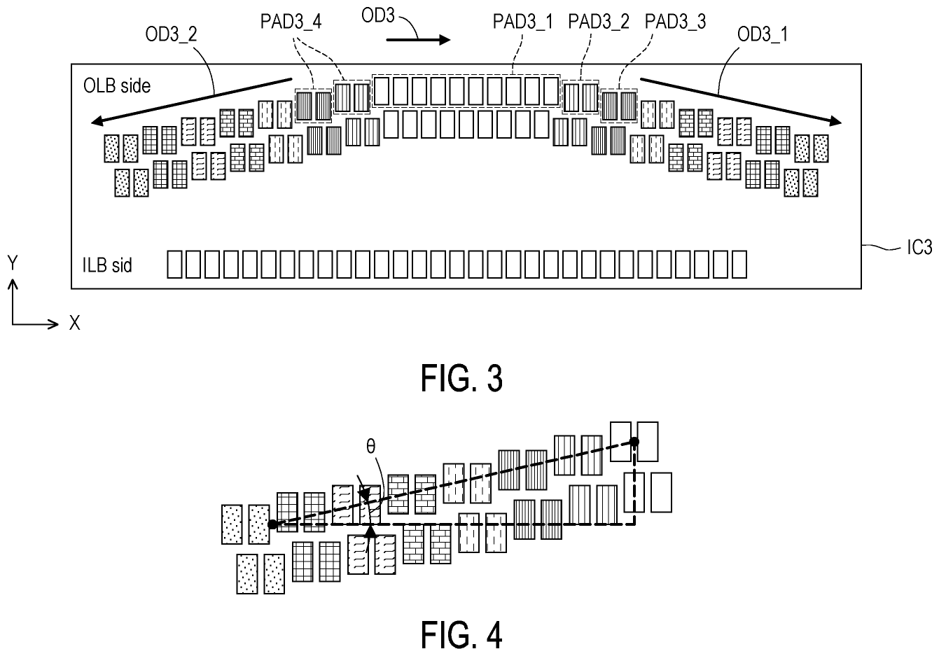

FIG. 3 is a schematic diagram of a pad layout of a semiconductor chip IC3 according to another embodiment of the disclosure. Details of the semiconductor chip IC3 shown in FIG. 3 may be deduced with reference to the related descriptions of the semiconductor chip IC2 shown in FIG. 2. Different from the embodiment shown in FIG. 2, in the embodiment shown in FIG. 3, the right pads are divided into multiple groups, and the left pads are also divided into multiple groups. The number of groups in the right pads may be determined according to the actual design. In these groups of right pads, the number of pads in each group may be determined according to the actual design. For example, as shown in FIG. 3, the number of pads in an X-axis direction in each group of right pads may be 2. In the same group, all pads in the same row have a same Y-axis position (Y coordinate). In other embodiments, the number of pads in the X-axis direction in each group may be different from each other. Details of the left pads may be deduced with reference to the related descriptions of the right pads and thus, will not be repeated hereinafter.

In the embodiment shown in FIG. 3, another pad group belonging to a second pad row is disposed on the ILB side (the second long side) of the semiconductor chip IC3.

In the embodiment shown in FIG. 3, the semiconductor chip IC3 includes a first pad group PAD3_1, a second pad group PAD3_2 and a third pad group PAD3_3, of a first pad row. The first pad group PAD3_1, the second pad group PAD3_2, the third pad group PAD3_3 and fourth pad groups PAD3_4 are disposed on the OLB side of the semiconductor chip IC3. The first distance from the first pad group PAD3_1 to the edge of the OLB side (the first long side) is different from a second distance from the second pad group PAD3_2 to the edge of the OLB side. The first pad group PAD3_1, the second pad group PAD3_2 and the third pad group PAD3_3 belong to a first pad row disposed at the OLB side (the first long side). The first pad group PAD3_1 comprises a plurality of pads which are closer to the middle of the first pad row than the second pad group PAD3_2. The second pad group PAD3_2 and the third pad group PAD3_3 are at a first side of the first pad group PAD3_1. The third pad group PAD3_3 is more far from the middle of the first pad row than the second pad group PAD3_2. A third distance from the third pad group PAD3_3 to the edge of the OLB side is different from the first distance and the second distance. For example, the second distance is larger than the first distance, and the third distance is larger than the second distance. That is, multiple pads of the first pad group PAD3_1 are disposed along an edge direction OD3 on the OLB side, while the second pad group PAD3_2 and the third pad group PAD3_3 are disposed along a first oblique direction OD3_1, as shown in FIG. 3. In the embodiment shown in FIG. 3, the number of pads of the first pad group PAD3_1 is different from that of the second pad group PAD3_2, and the number of pads of the second pad group PAD3_2 and the third pad group PAD3_3 are the same as each other. As shown in FIG. 3, the number of pads of the first pad group PAD3_1 is greater than the number of pads of the second pad group PAD3_2 and greater than the number of pads of the third pad group PAD3_3, and each pad group of the second pad group PAD3_2 and the third pad group PAD3_3 comprises at least one pad.

The semiconductor chip IC3 further includes multiple fourth pad groups PAD3_4. The fourth pad groups PAD3_4 belong to the first pad row. The fourth pad groups PAD3_4 are disposed along a second oblique direction OD3_2 different from the first oblique direction OD3_1. The fourth pad groups PAD3_4 are disposed on the left side (second side) of the first pad group PAD3_1, while the second pad group PAD3_2 and the third pad group PAD3_3 are disposed on the right side of the first pad group PAD3_1. The fourth distance from the fourth pad group PAD3_4 to the edge of the OLB side (the first long side) is larger than the first distance from the first pad group PAD3_1 to the edge of the OLB side. Details of the fourth pad groups PAD3_4 may be deduced with reference to the related descriptions of the second pad group PAD3_2 and the third pad group PAD3_3 and thus, will not be repeated hereinafter.

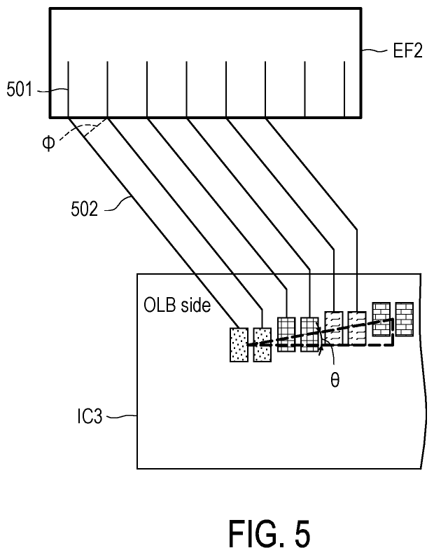

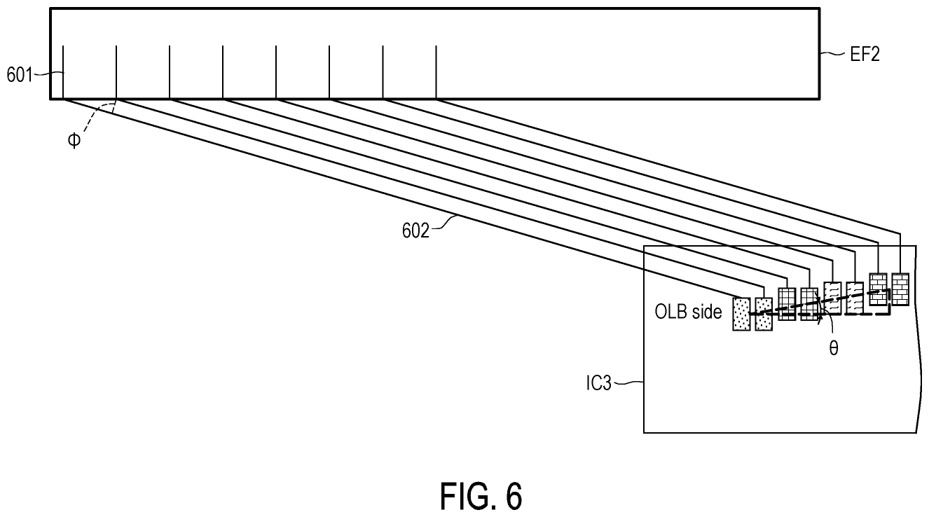

FIG. 4 is a schematic diagram illustrating a layout of the left pads (the fourth pad groups PAD3_4) shown in FIG. 3 according to an embodiment of the disclosure. Details of the right pads shown in FIG. 3 (such as the second pad group PAD3_2 and the third pad group PAD3_3) may be deduced with reference to the related descriptions of FIG. 4 and thus, will not be repeated hereinafter. With reference to FIG. 3 and FIG. 4. In the embodiment shown in FIG. 4, the left pads (the fourth pad groups PAD3_4) have a descending slope, that is, a descending angle θ shown in FIG. 4 which is an included angle between the oblique direction and the horizontal axis that the first long side is along. The descending angle θ will affect the panel size supported by the semiconductor chip IC3. In order to be applicable to large-size display panels, the descending angle θ of the outer pad groups is less than or equal to an included angle φ between the lower side of the effective function region EF2 (which is along the horizontal axis) and the fan-out wires connected with the outer driving lines of the display panel (refer to the following description of FIG. 5 and FIG. 6 for details).

FIG. 5 is a schematic diagram illustrating a layout of the fan-out region between the left pads (the fourth pad groups PAD3_4) shown in FIG. 3 and the display panel according to an embodiment of the disclosure. Details of the right pads shown in FIG. 3 (such as the second pad group PAD3_2 and the third pad group PAD3_3) may be deduced with reference to the related descriptions of FIG. 5, and thus, will not be repeated hereinafter. With reference to FIG. 3 and FIG. 5, in the embodiment shown in FIG. 5, the pads of the semiconductor chip IC3 are connected to different driving lines of the effective function region EF2 of the display panel via the fan-out wires of the fan-out region. The smaller the panel size, the larger the included angle φ between the fan-out wires 502 and the horizontal axis.

FIG. 6 is a schematic diagram illustrating a layout of the fan-out region between the left pads (the fourth pad groups PAD3_4) shown in FIG. 3 and the large-size display panel according to an embodiment of the disclosure. Details of the right pads shown in FIG. 3 (such as the second pad group PAD3_2 and the third pad group PAD3_3) may be deduced with reference to the related descriptions of FIG. 6, and thus, will not be repeated hereinafter. With reference to FIG. 3 and FIG. 6, in the embodiment shown in FIG. 6, the pads of the semiconductor chip IC3 are connected to different driving lines of the effective function region EF2 of the large-size display panel via the fan-out wires of the fan-out region. As shown in FIG. 6, the included angle between fan-out wires 602 connected to the outer driving lines 601 of the effective function region EF2 and the horizontal axis is denoted as φ. Based on the limitations of design parameters such as resolution, pixel size, fan-out pitch, bump pitch and the like, the larger the panel size is larger, the smaller the included angle φ between the fan-out wires 602 outside the fan-out region and the horizontal axis. Therefore, in the semiconductor chip IC3, the descending angle θ of the left (right) pads on the OLB side needs to be less than or equal to the included angle φ between the fan-out wires and the horizontal axis, so as to support the large-size display panel.

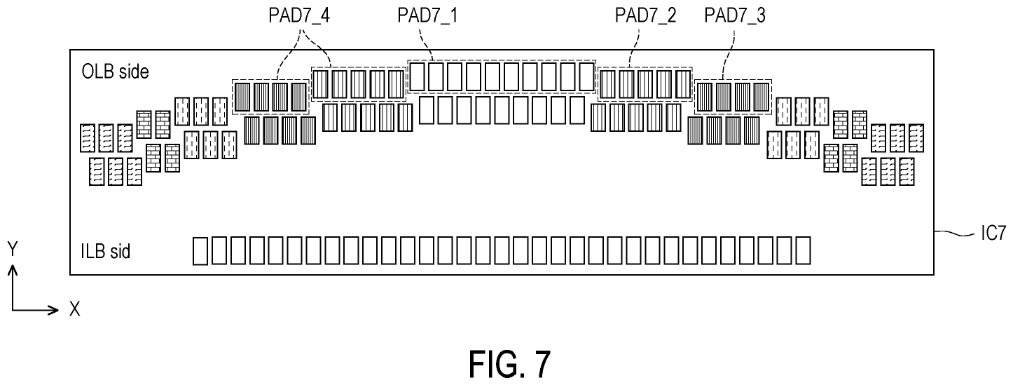

FIG. 7 is a schematic diagram of a pad layout of a semiconductor chip IC7 according to another embodiment of the disclosure. In the embodiment shown in FIG. 7, the pads on the OLB side are divided into multiple groups, such as a first pad group PAD7_1, a second pad group PAD7_2, a third pad group PAD7_3 and fourth pad groups PAD7_4. Details of the semiconductor chip IC7, the first pad group PAD7_1, the second pad group PAD7_2, the third pad group PAD7_3, and the fourth pad groups PAD7_4 shown in FIG. 7 may be deduced from the related descriptions of the semiconductor chip IC3, the first pad group PAD3_1, the second pad group PAD3_2, the third pad group PAD3_3 and the fourth pad groups PAD3_4 shown in FIG. 3. Different from the embodiment shown in FIG. 3, in the embodiment shown in FIG. 7, the number of pads of each pad group in the right (or left) pad on the OLB side may be different from each other. For example, as shown in FIG. 7, in the right pads on the OLB side, the number of pads of the first pad group PAD7_1 is 10, the number of pads of the second pad group PAD7_2 is 5, and the number of pads of the third pad group PAD7_3 is 4.

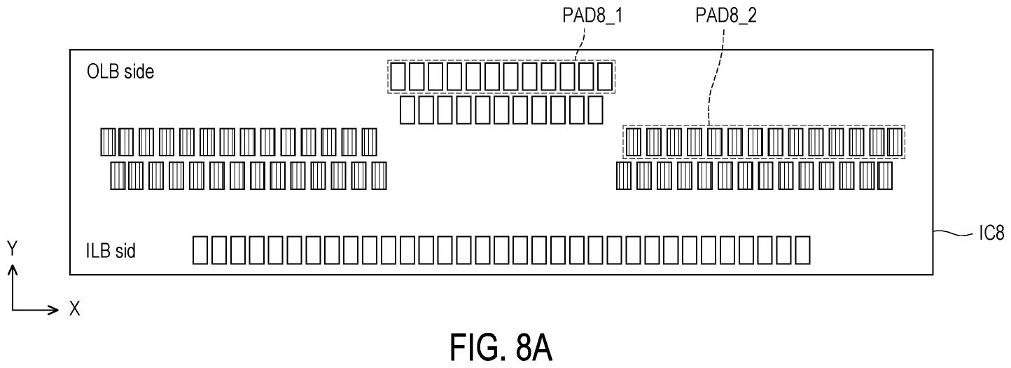

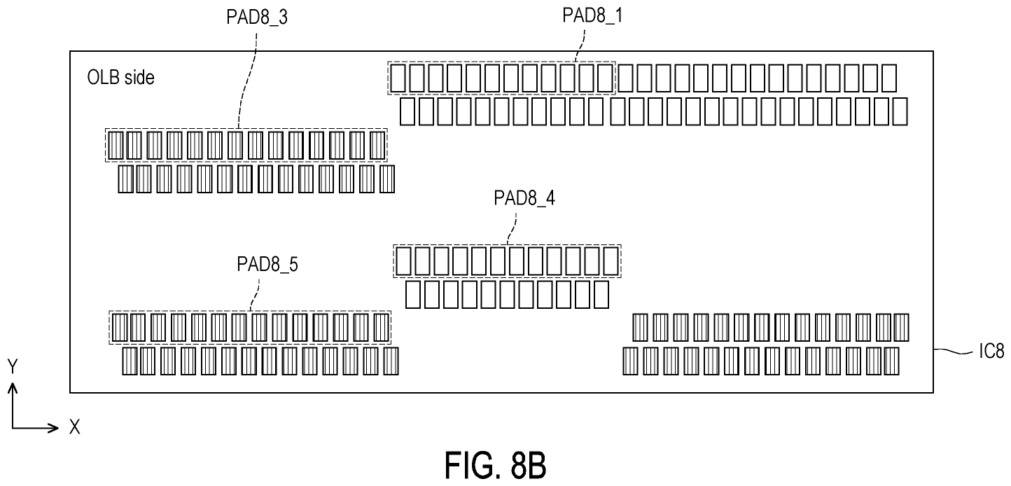

FIG. 8A is a schematic diagram of a pad layout of a semiconductor chip IC8 according to yet another embodiment of the disclosure. In the embodiment shown in FIG. 8A, the pads on the OLB side are divided into multiple groups, such as a first pad group PAD8_1 and a second pad group PAD8_2. Details of the semiconductor chip IC8, the first pad group PAD8_1, and the second pad group PAD8_2 shown in FIG. 8A may be deduced with reference to the related descriptions of the semiconductor chip IC3, the first pad group PAD3_1, and the second pad group PAD3_2 shown in FIG. 3. Different from the embodiment shown in FIG. 3, in the embodiment shown in FIG. 8A, all pads in the left pads on the OLB side are defined as one group (the second pad group PAD8_2), while all pads in the right pads on the OLB side are defined as another group. In the same group, all pads in the same row have the same vertical position (have the same vertical coordinates).

FIG. 8B is a schematic diagram of a pad layout of a semiconductor chip according to another embodiment of the disclosure. In the embodiment shown in FIG. 8B, the semiconductor chip comprises a first pad group PAD8_1, a second pad group PAD8_3, a third pad group PAD8_4, and a fourth pad group PAD8_5. The first pad group PAD8_1 is disposed at a first long side (the OLB side) of the semiconductor chip. The second pad group PAD8_3 is disposed at the OLB side, wherein a first distance from the first pad group PAD8_1 to the edge of the OLB side is different from a second distance from the second pad group PAD8_3 to the edge of the OLB side, the first pad group PAD8_1 and the second pad group PAD8_3 belong to a first pad row disposed at the OLB side, and the first pad group PAD8_1 comprises a plurality of pads which are closer to the middle of the first pad row than the second pad group PAD8_3.

The third pad group PAD8_4 is disposed at a second long side (the ILB side) of the semiconductor chip. The fourth pad group PAD8_5 is disposed at the ILB side, wherein a third distance from the third pad group PAD8_4 to the edge of the ILB side is different from a fourth distance from the fourth pad group PAD8_5 to the edge of the ILB side, the third pad group PAD8_4 and the fourth pad group PAD8_5 belong to a second pad row disposed at the ILB side, and the third pad group PAD8_4 comprises a plurality of pads which are closer to the middle of the second pad row than the forth pad group PAD8_5.

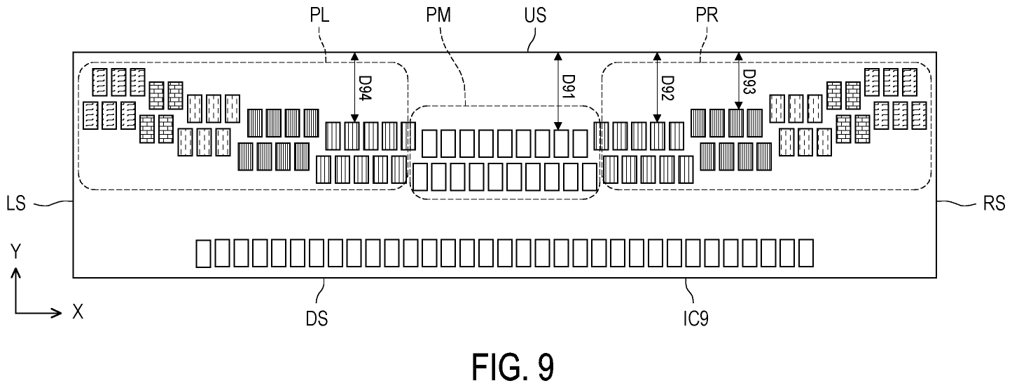

FIG. 9 is a schematic diagram of a pad layout of a semiconductor chip IC9 according to still another embodiment of the disclosure. The middle pads PM, the left pads PL and the right pads PR belong to the first pad row. The right pads PR are arranged at a first side of the middle pads PM. The left pads PL are arranged at a second side of the middle pads PM. In the embodiment shown in FIG. 9, middle pads PM (the first pad group) of the pads on the OLB side are arranged in the horizontal direction, but the vertical coordinates of the middle pads PM are farther away from an edge US on the OLB side of the semiconductor chip IC9 than those of left pads PL and right pads PR, that is, farther away from the effective function region EF2 of the display panel. When viewed in the vertical direction, among the pads on the OLB side, the left pads PL gradually approach the edge US on the OLB side from the middle pads PM toward a left edge LS of the semiconductor chip IC9, and right pads PR gradually approach the edge US on the OLB side from the middle pads PM toward a right edge RS of the semiconductor chip IC9. The second distance D92 is smaller than the first distance D91, and the third distance D93 is smaller than the second distance D92. The fourth distance D94 is smaller than the first distance D91. In other words, the middle pads PM are farthest from the effective function region EF2 of the display panel, and the left pads PL and the right pads PR are arranged to be closer to the effective function region EF2 of the display panel as they go outward. In the embodiment shown in FIG. 9, the way of grouping the pads in the left pads PL and the right pads PR of the OLB side may be similar to that in FIG. 7. In this way, the shape of the pads on the OLB side as a whole seems that the middle pads PM are arranged to be descending toward the direction of an edge DS on the ILB side. The pads on the OLB side of the semiconductor chip IC9 may be referred to as descending-type pads. Therefore, the position of the semiconductor chip IC9 may be advanced toward the fan-out region FR2, such that the distance HF' between the semiconductor chip IC9 and the effective function region EF2 of the display panel may be smaller than the height HF of the fan-out region FR2. The reduction in the distance HF' from the semiconductor chip IC9 to the effective function region EF2 indicates that the width of the border region BRD2 of the display panel may be further reduced.

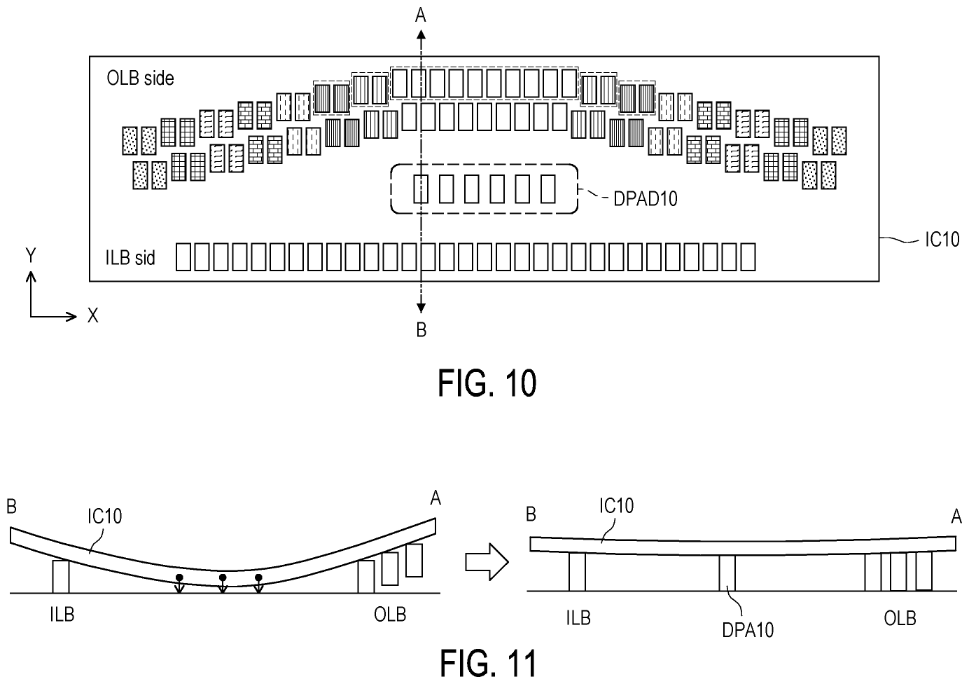

FIG. 10 is a schematic diagram of a pad layout of a semiconductor chip IC10 according to yet another embodiment of the disclosure. In the embodiment shown in FIG. 10, multiple pad groups belonging to the first pad row are disposed on the OLB side (the first long side) of the semiconductor chip IC10, and another pad group belonging to a second pad row is disposed on the ILB side (the second long side) of the semiconductor chip IC10. Details of the pads on the OLB side and the pads on the ILB side shown in FIG. 10 may be deduced with reference to the related descriptions of the pads on the OLB side and the pads on the ILB side shown in FIG. 3, and thus, will not be repeated hereinafter. Different from the embodiment shown in FIG. 3, in the embodiment shown in FIG. 10, the semiconductor chip IC10 is arranged with dummy pads (a pad group DPAD10 shown in FIG. 10), wherein the pad group DPAD10 is disposed between the first pad row on the OLB side and the second pad row on the ILB side.

FIG. 11 is a schematic diagram illustrating two cross-sections of the semiconductor chip IC10 shown along a cross-section line AB in FIG. 10 under different design conditions according to yet another embodiment of the disclosure. The schematic cross-sectional diagram on the left side of FIG. 11 shows a situation where the semiconductor chip IC10 is subjected to bonding stress without dummy pads (the pad group DPAD10). The schematic cross-sectional diagram on the right side of FIG. 11 shows a situation where the semiconductor chip IC10 is subjected to bonding stress when the dummy pads (the pad group DPAD10) are arranged. Comparing the left side of FIG. 11 with the right side of FIG. 11, it can be seen that arranging the dummy pads (the pad group DPAD10) between the pads on the OLB side and the pads on the ILB side can prevent the problem of uneven bonding stress. The shape of the dummy pads may be determined according to the actual design, such as rectangle, square, circle, polygon or other geometric shapes. The number and pitch of dummy pads may be determined according to the actual design.

The electrical state of the pad group DPAD10 (dummy pad) may be arranged according to the actual design. For example, in some embodiments, pads of the pad group DPAD10 are in a floating state or a HI-Z state (high impedance state). In other embodiments, all pads of the pad group DPAD10 may be coupled to at least one certain DC voltage to provide electrostatic discharge (ESD) protection capability. The DC voltage may be set according to the actual design. For example, the DC voltage may be a ground voltage or other fixed reference voltages.

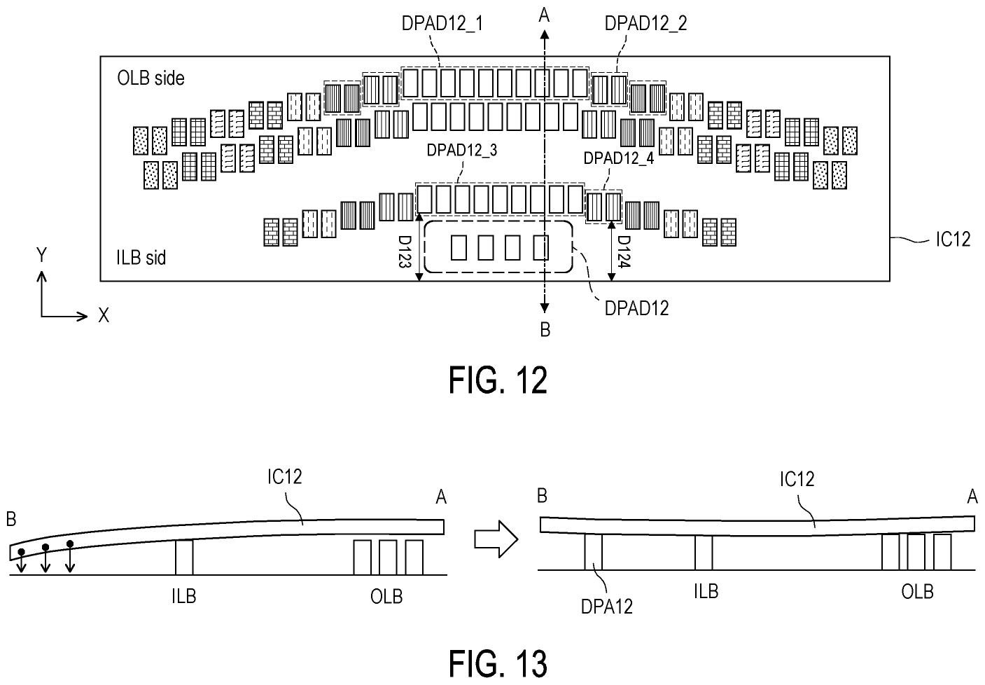

FIG. 12 is a schematic diagram illustrating a layout of the descending-type pads of a semiconductor chip IC12 according to another embodiment of the disclosure. In the embodiment shown in FIG. 12, multiple pad groups (e.g. the first pad group PAD12_1 and the second pad group PAD12_2) are arranged on the OLB side of the semiconductor chip IC12, while multiple pad groups (e.g. the third pad group PAD12_3 and the fourth pad group PAD12_4) are arranged on the ILB side of the semiconductor chip IC12. Details of the pads on the OLB side shown in FIG. 12 may be deduced with reference to the related descriptions of the pads on the OLB side shown in FIG. 3 and thus, will not be repeated hereinafter.

The third pad group PAD12_3 is disposed at a second long side (the ILB side) of the semiconductor chip IC12. The fourth pad group PAD12_4 is disposed at the ILB side, wherein a third distance D123 from the third pad group PAD12_3 to the edge of the ILB side is different from a fourth distance D124 from the fourth pad group PAD12_4 to the edge of the ILB side. For example, the third distance D123 is greater than the fourth distance D124. In other embodiment, the third distance D123 is smaller than the fourth distance D124. The third pad group PAD12_3 and the fourth pad group PAD12_4 belong to a second pad row disposed at the ILB side, and the third pad group PAD12_3 comprises a plurality of pads which are closer to the middle of the second pad row than the forth pad group PAD12_4.

Different from the embodiment shown in FIG. 3, in the embodiment shown in FIG. 12, the semiconductor chip IC12 is arranged with dummy pads (a pad group DPAD12 shown in FIG. 12). The pad group DPAD12 is disposed between the third pad group PAD12_3 on the ILB side and the edge of the ILB side. The pads of the pad group DPAD12 are bump pads in a floating state.

Different from the embodiment shown in FIG. 10, in the embodiment shown in FIG. 12, the pads on the ILB side are also arranged as descending-type pads. That is, among the pads on the ILB side, the pads closer to the two short sides of the chip are farther away from the effective function region EF2 of the display panel. The layout shown in FIG. 12 may maintain the minimum pitch between each pad on the OLB side and each pad on the ILB side in the vertical direction. In the semiconductor chip IC12, the dummy pads (the pad group DPAD12) are arranged between the pads on the ILB side and the edge of the ILB side.

FIG. 13 is a schematic diagram illustrating two cross-sections of the semiconductor chip IC12 along the cross-section line AB shown in FIG. 12 under different design conditions according to yet another embodiment of the disclosure. The schematic cross-sectional diagram on the left side of FIG. 13 shows a situation where the semiconductor chip IC12 is subjected to bonding stress without the dummy pads (the pad group DPAD12). The schematic cross-sectional diagram on the right side of FIG. 13 shows a situation where the semiconductor chip IC12 is subjected to bonding stress when the dummy pads (the pad group DPAD12) are arranged. Comparing the left side of FIG. 13 with the right side of FIG. 13, it can be seen that the dummy pads (the pad group DPAD12) arranged between the pads on the ILB side and the edge of the ILB side can prevent the problem of uneven bonding stress. Details of the pad group DPAD12 shown in FIGS. 12 and 13 may be deduced with reference to the related descriptions of the pad group DPAD10 shown in FIG. 10 and FIG. 11, and thus, will not be repeated hereinafter.

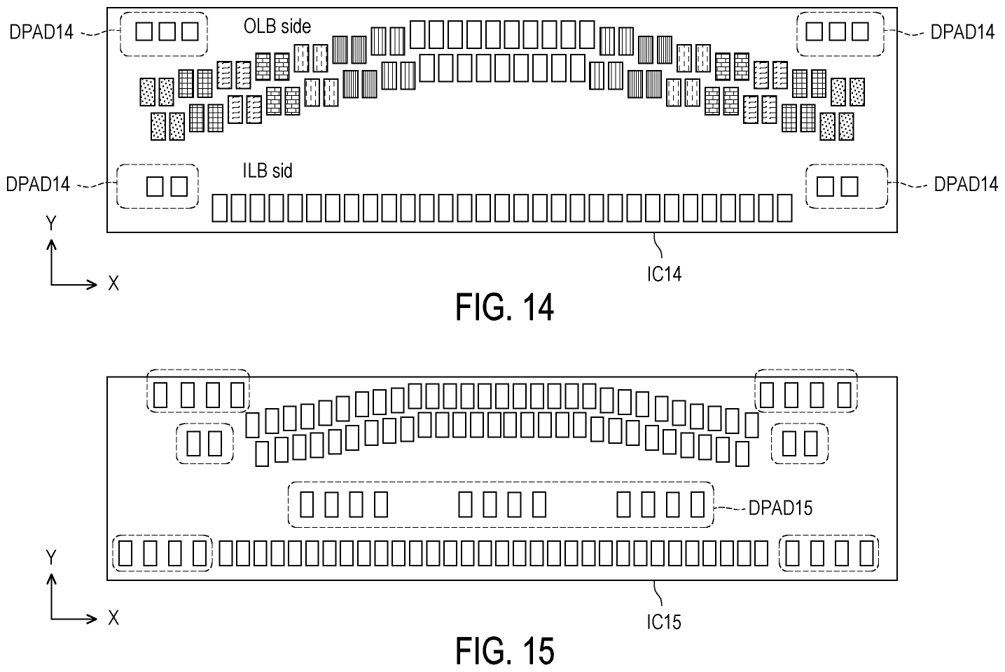

FIG. 14 is a schematic diagram illustrating a layout of the descending-type pads of a semiconductor chip IC14 according to still yet another embodiment of the disclosure. Details of the embodiment shown in FIG. 14 may be deduced with reference to the related descriptions of FIG. 10. Different from the embodiment shown in FIG. 10, in the embodiment shown in FIG. 14, the dummy pads are arranged in other regions of the driving chip. For example, the dummy pads (a pad group DPAD14) may be arranged between the pads on the OLB side and the display panel (near the edge of the OLB side), and (or) be arranged in an area (such as near the edge of the ILB side) under the pads on the OLB side without affecting the arrangement of the pads on the ILB side. The dummy pads (the pad group DPAD14) can prevent the problem of uneven bonding stress.

FIG. 15 is a schematic diagram illustrating a layout of the descending-type pads of a semiconductor chip IC15 according to still another embodiment of the disclosure. In the embodiment shown in FIG. 15, the dummy pads may be arranged in multiple regions of the semiconductor chip IC15, for example, a pad group DPAD15 between the pads on the OLB side and the pads on the ILB side (refer to the related descriptions of FIG. 10 for details) and in other regions (refer to the related descriptions of FIG. 14 for details).

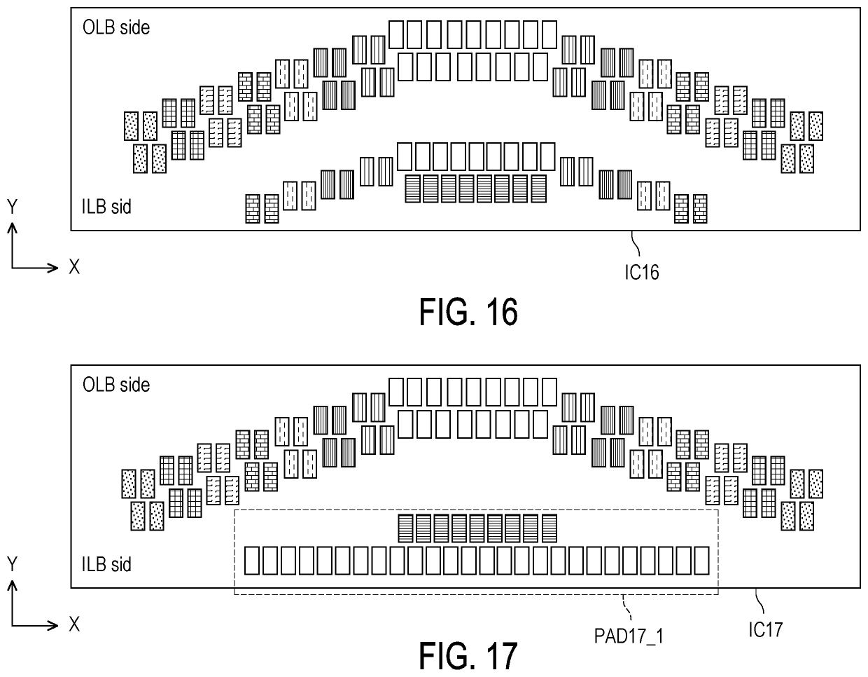

FIG. 16 is a schematic diagram illustrating a layout of the descending-type pads of a semiconductor chip IC16 according to another embodiment of the disclosure. In the embodiment shown in FIG. 16, the pads on the OLB side are arranged as descending-type pads, and the pads on the ILB side are also arranged as descending-type pads. Similar to the layout of the pads on the OLB side, the pads on the ILB side near the two short sides of the semiconductor chip IC16 are farther away from the effective function region EF2 of the display panel. In the embodiment shown in FIG. 16, the middle part of the pads on the ILB side is arranged in multiple rows (for example, two or more rows).

FIG. 17 is a schematic diagram illustrating a layout of the descending-type pads of a semiconductor chip IC17 according to still another embodiment of the disclosure. Details of the embodiment shown in FIG. 17 may be deduced with reference to the related descriptions of FIG. 3. Different from the embodiment shown in FIG. 3, in the embodiment shown in FIG. 17, a pad PAD17_1 on the ILB side is arranged in multiple rows (for example, two or more rows).

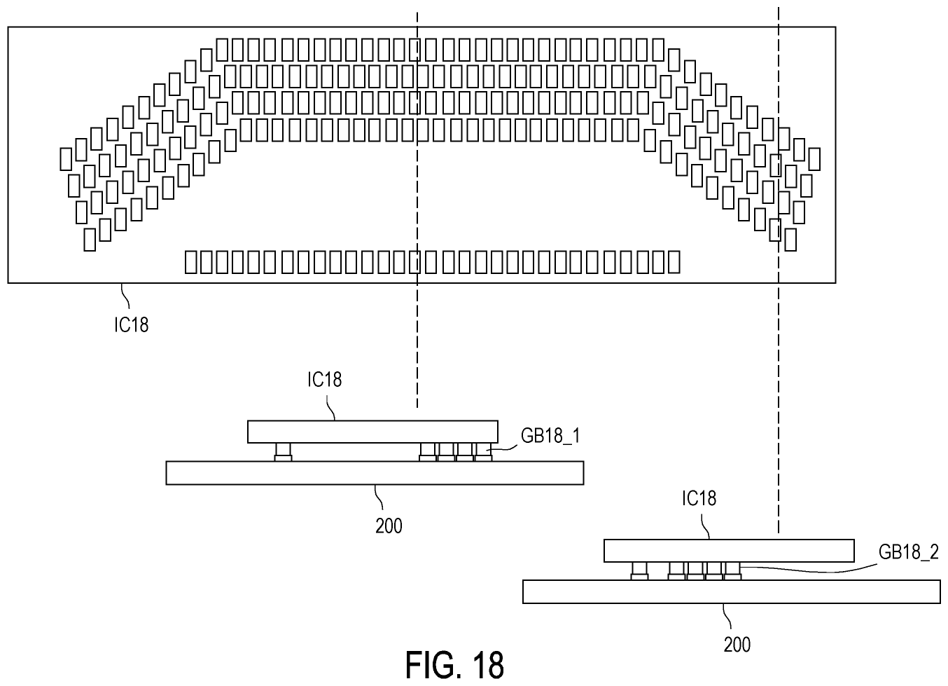

FIG. 18 is a schematic diagram illustrating a layout of the descending-type pads of a semiconductor chip IC18 according to still yet another embodiment of the disclosure. The upper part of FIG. 18 shows a top view of the semiconductor chip IC18, while the lower part of FIG. 18 shows two schematic cross-sectional diagrams along different cross-section lines of the semiconductor chip IC18. In the embodiment shown in FIG. 18, the pads on the OLB side may be divided into a left part, a middle part and a right part, wherein the middle pads are arranged in a horizontal direction, while the left pads and the right pads are arranged in different oblique directions. A conductive bump (such as a gold bump) is bonded on each pad of the semiconductor chip IC18. For example, a conductive bump GB18_1 is arranged on the pads of the first pad group of the semiconductor chip IC18, and a conductive bump GB18_2 is arranged on the pads of the second pad group of the semiconductor chip IC18. The conductive bumps may be bonded to pads (conductive material layers) provided on the glass substrate of the display panel 200. According to the actual design, the descriptions of the conductive bump shown in FIG. 18 may be applied to any of the embodiments described above and later.

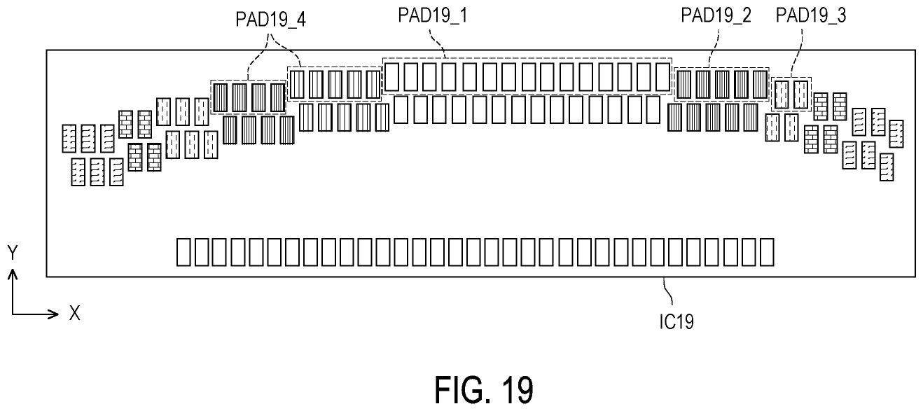

FIG. 19 is a schematic diagram illustrating an asymmetric layout the of descending-type pads of a semiconductor chip IC19 according to another embodiment of the disclosure. The semiconductor chip IC19 shown in FIG. 19 includes a first pad group PAD19_1, a second pad group PAD19_2 and a third pad group PAD19_3. Details of the first pad group PAD19_1, the second pad group PAD19_2 and the third pad group PAD19_3 shown in FIG. 19 may be deduced with reference to the related descriptions of the first pad group PAD3_1, the second pad group PAD3_2, and the third pad group PAD3_3 shown in FIG. 3. Different from the embodiment shown in FIG. 3, in the embodiment shown in FIG. 19, the number of pads of the first pad group PAD19_1, the second pad group PAD19_2, and the third pad group PAD19_3 are different from each other. Furthermore, the pads of the semiconductor chip IC19 shown in FIG. 19 are arranged asymmetrically. In other words, the arrangement of the number of pads of the left pads (such as multiple fourth pad groups PAD19_4) of FIG. 19 may be different from the arrangement of the number of pads of the right pads (such as the second pad group PAD19_2 and the third pad group PAD19_3) of FIG. 3. According to actual design, in other embodiments, the number of pads of the first pad group PAD19_1, the second pad group PAD19_2, the third pad group PAD19_3, and the fourth pad groups PAD19_4 may be different from each other.

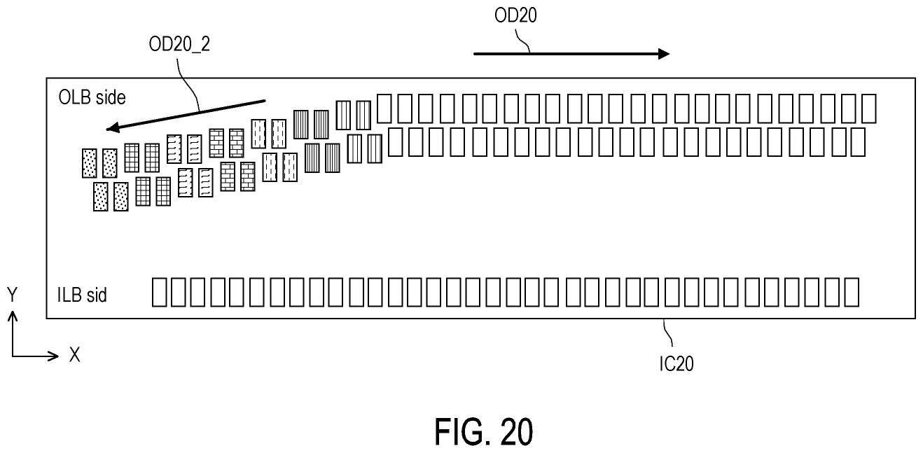

FIG. 20 is a schematic diagram illustrating an asymmetric layout of the descending-type pads of a semiconductor chip IC20 according to yet another embodiment of the disclosure. Details of the embodiment shown in FIG. 20 may be deduced with reference to the related descriptions of FIG. 3. Different from the embodiment shown in FIG. 3, among the pads on the OLB side of the semiconductor chip IC20 shown in FIG. 20, the left pads are arranged along an oblique direction OD20_2, while the middle pads and the right pads are arranged along an edge direction OD20 on the OLB side, as shown in FIG. 20.

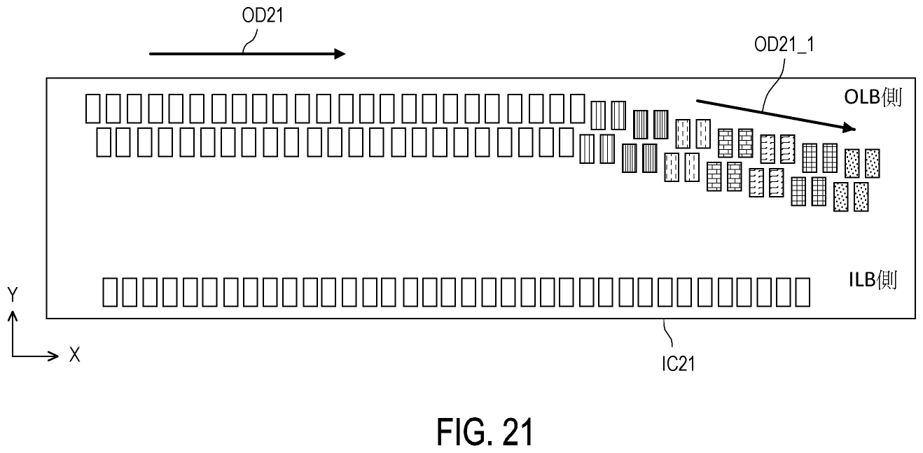

FIG. 21 is a schematic diagram illustrating an asymmetric layout of the descending-type pads of a semiconductor chip IC21 according to another embodiment of the disclosure. Details of the embodiment shown in FIG. 21 may be deduced with reference to the related descriptions of FIG. 3. Different from the embodiment shown in FIG. 3, among the pads on the OLB side of the semiconductor chip IC21 shown in FIG. 21, the right pads are arranged along an oblique direction OD21_1, while the middle pads and the left pads are arranged along an edge direction OD21 on the OLB side, as shown in FIG. 21.

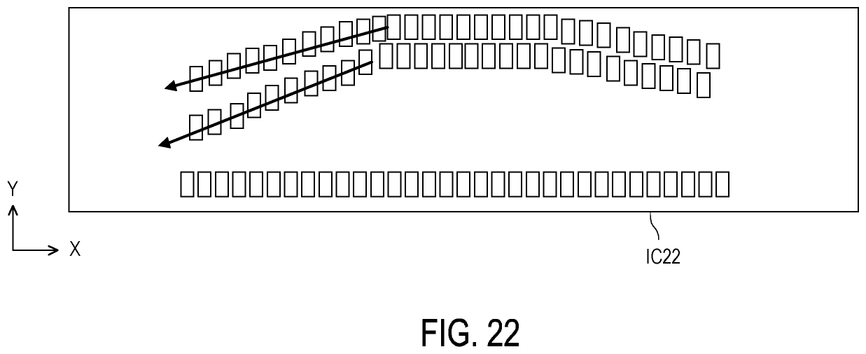

FIG. 22 is a schematic diagram illustrating a layout of the descending-type pads of a semiconductor chip IC22 according to still yet another embodiment of the disclosure. Details of the embodiment shown in FIG. 22 may be deduced with reference to the related descriptions of FIG. 2 and/or FIG. 3. Different from the embodiments shown in FIGS. 2 and 3, among the pads on the OLB side of the semiconductor chip IC22 shown in FIG. 22, the descending angle θ of the pads in different rows may be different from each other.

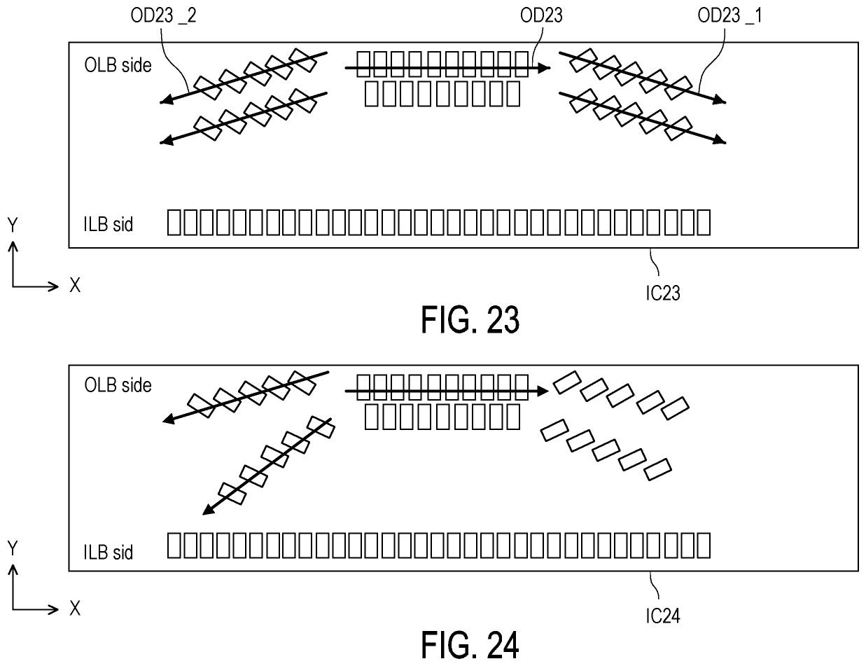

FIG. 23 is a schematic diagram illustrating a layout of the descending-type pads of a semiconductor chip IC23 according to still yet another embodiment of the disclosure. In the right and left pads on the OLB side of the semiconductor chip IC23 shown in FIG. 23, the direction of the connection between the center of each pad in the right and left pads on the OLB side of the semiconductor IC23 is an oblique direction OD23_1 and an oblique direction OD23_2, while the direction of the connection between the center of each pad in the middle pads is an edge direction OD23, which is different from the oblique direction OD23_1 and the oblique direction OD23_2. In other words, a center axis direction of each pad in the left and right pads on the OLB side may be different from a center axis direction of each pad in the middle pads (which is a vertical direction).

FIG. 24 is a schematic diagram illustrating a layout of the descending-type pads of a semiconductor chip IC24 according to still yet another embodiment of the disclosure. Details of the embodiment shown in FIG. 24 may be deduced with reference to the related descriptions of FIG. 23. Different from the embodiment shown in FIG. 23, in the semiconductor chip IC24 shown in FIG. 24, the descending angle θ of different rows of pads on the OLB side may be different from each other.

In summary, the semiconductor chips described in the above embodiments have a descending-type pad layout. The descending-type pad layout can facilitate further advancement of the position of the semiconductor chip toward the fan-out region FR2 of the display panel 200. Therefore, the pad layout of the semiconductor chip can facilitate the reduction in the width of the border region BRD2 of the display panel 200.

Although the disclosure has been recited with examples as above, it is not intended to limit the disclosure. Anyone with ordinary knowledge in the art may make various modifications and variations without departing from the spirit and scope of the disclosure. Therefore, the scope of protection of the disclosure shall be subject to the scope defined by the following claims.

What is claimed is:

1. A semiconductor chip, driving a display panel, the semiconductor chip comprising:
a first pad group, disposed at a first long side of the semiconductor chip; and
a second pad group, disposed at the first long side, wherein a first distance from the first pad group to an edge of the first long side is different from a second distance from the second pad group to the edge of the first long side, the first pad group and the second pad group belong to a first pad row disposed at the first long side, and the first pad group comprises a plurality of pads which are closer to the middle of the first pad row than the second pad group.

2. The semiconductor chip as described in claim 1, further comprising:
a third pad group, arranged on the first long side and belonging to the first pad row, wherein the second pad group and the third pad group are at a first side of the first pad group, the third pad group is more far from the middle of the first pad row than the second pad group, and a third distance from the third pad group to the edge of the first long side is different from the first distance and the second distance.

3. The semiconductor chip as described in claim 2, wherein the second distance is larger than the first distance and the third distance is larger than the second distance.

4. The semiconductor chip as described in claim 2, wherein the second distance is smaller than the first distance, and the third distance is smaller than the second distance.

5. The semiconductor chip as described in claim 2, wherein the number of pads of the first pad group is greater than the number of pads of the second pad group and greater than the number of pads of the third pad group, and each pad group of the second pad group and the third pad group comprises at least one pad.

6. The semiconductor chip as described in claim 5, wherein the number of pads of the second pad group and the number of pads of the third pad group are different.

7. The semiconductor chip as described in claim 5, wherein the number of pads of the second pad group and the number of pads of the third pad group are the same.

8. The semiconductor chip as described in claim 3, further comprising:
a fourth pad group, belonging to the first pad row and at a second side of the first pad group, and a fourth distance from the fourth pad group to the edge of the first long side is larger than the first distance.

9. The semiconductor chip as described in claim 4, further comprising:
a fourth pad group, belonging to the first pad row and at a second side of the first pad group, and a fourth distance from the fourth pad group to the edge of the first long side is smaller than the first distance.

10. The semiconductor chip as described in claim 1, wherein the first long side is a side where most of output lead bump pads of the semiconductor chip are disposed.

11. The semiconductor chip as described in claim 1, further comprising:
a second pad row disposed at a second long side of the semiconductor chip; and
a third pad group, disposed along a long axis of the semiconductor chip and between the first pad row and the second pad row.

12. The semiconductor chip as described in claim 11, wherein pads of the third pad group are in a floating state or connected to a ground level.

13. The semiconductor chip as described in claim 11, wherein pads of the fourth pad group are coupled to at least one DC voltage.

14. The semiconductor chip as described in claim 1, further comprising:
a third pad group, disposed at a second long side of the semiconductor chip.
a fourth pad group, disposed at the second long side, wherein a third distance from the third pad group to an edge of the second long side is different from a fourth distance from the fourth pad group to the edge of the second long side, the third pad group and the fourth pad group belong to a second pad row disposed at the second long side, and the third pad group comprises a plurality of pads which are closer to the middle of the second pad row than the forth pad group.

15. The semiconductor chip as described in claim 14, wherein the third distance is greater than the fourth distance, and semiconductor chip further comprises a fifth pad group disposed between the third pad group and the edge of the second side.

16. The semiconductor chip as described in claim 15, wherein pads of the fifth pad group are bump pads in a floating state.

17. The semiconductor chip as described in claim 14, wherein the third distance is smaller than the fourth distance.

18. The semiconductor chip as described in claim 1, where a conductive bump is bonded on each pad of the first pad group and the second ad group.

19. The semiconductor chip as described in claim 1, wherein a center axis direction of the pads of the first pad group is different from a center axis direction of the pads of the second pad.
